(19) United States
(12) Patent Application Publication
(10) Pub. No.: US 2026/0255796 A1
(43) Pub. Date: Aug. 27, 2026

(54) ELECTRONIC DEVICE

(71) Applicant: Samsung Display Co., Ltd., Yongin-si (KR)

(72) Inventors: Minki YANG, Yongin-si (KR); HYUNAE PARK, Yongin-si (KR); JUNWON CHOI, Yongin-si (KR); Daehyun KIM, Yongin-si (KR)

(21) Appl. No.: 19/348,659

(22) Filed: Oct. 2, 2025

(30) Foreign Application Priority Data
Feb. 21, 2025 (KR) 10-2025-0022789

(51) Int. Cl. H10K 59/121; H10K 59/123; H10K 59/131; H10K 59/80

(52) U.S. Cl. CPC H10K 59/1213; H10K 59/123; H10K 59/131; H10K 59/80515

(57) ABSTRACT

An electronic device includes: a display panel including a circuit layer, and a light emitting element layer. The circuit layer includes: a base layer; a transistor on the base layer; a connecting electrode electrically connected with the transistor; and a plurality of data lines above the transistor. The light emitting element layer includes: a first anode on the circuit layer, and electrically connected with the connecting electrode; a first emissive layer on the first anode; and a cathode on the first emissive layer. The plurality of data lines includes: a first data line extending in a first direction; a second data line spaced from the first data line in a second direction crossing the first direction; and a third data line spaced from the second data line in the second direction. Each of the plurality of data lines overlaps with the first anode in a plan view.

### CROSS-REFERENCE TO RELATED APPLICATION

The present application claims priority to and the benefit of Korean Patent Application No. 10-2025-0022789, filed on Feb. 21, 2025, in the Korean Intellectual Property Office, the entire disclosure of which is incorporated by reference herein.

### BACKGROUND

Aspects of embodiments of the present disclosure relate to an electronic device having an improved display quality.

Among display devices, an organic light emitting display device displays an image using an organic light emitting diode that generates light through the recombination of electrons and holes. The organic light emitting display device has a rapid response speed, and is driven by a low power consumption.

The organic light emitting display device includes pixels connected to data lines and scan lines. Each of the pixels includes an organic light emitting diode, and a circuit for controlling an amount of current flowing through the organic light emitting diode. The organic light emitting diode generates light having a certain luminance in response to the amount of current transferred from the circuit.

The above information disclosed in this Background section is for enhancement of understanding of the background of the present disclosure, and therefore, it may contain information that does not constitute prior art.

### SUMMARY

Embodiments of the present disclosure may be directed to an electronic device having an improved display quality.

According to one or more embodiments of the present disclosure, an electronic device includes: a display panel including a circuit layer, and a light emitting element layer on the circuit layer. The circuit layer includes: a base layer; a transistor on the base layer; a connecting electrode electrically connected with the transistor; and a plurality of data lines above the transistor. The light emitting element layer includes: a first anode on the circuit layer, and electrically connected with the connecting electrode; a first emissive layer on the first anode; and a cathode on the first emissive layer. The plurality of data lines includes: a first data line extending in a first direction; a second data line spaced from the first data line in a second direction crossing the first direction; and a third data line spaced from the second data line in the second direction. Each of the plurality of data lines overlaps with the first anode in a plan view.

In an embodiment, the first data line may be configured to receive a first data signal, the second data line may be configured to receive a second data signal different from the first data signal, and the third data line may be configured to receive a third data signal different from the first data signal and the second data signal.

In an embodiment, the first emissive layer may be configured to emit a blue light.

In an embodiment, the light emitting element layer may further include: a second anode on the circuit layer; a second emissive layer on the second anode; a third anode on the circuit layer; and a third emissive layer on the third anode.

In an embodiment, the plurality of data lines may not overlap with the second anode and the third anode in a plan view.

In an embodiment, the first anode may include a first portion extending in the first direction, a second portion extending from the first portion in the second direction, and a third portion extending from the first portion in the second direction.

In an embodiment, in a plan view, the first data line and the second data line may overlap with the first portion, and the third data line may overlap with the second portion and the third portion.

In an embodiment, the first emissive layer may include a first emissive portion corresponding to a shape of the first portion, a second emissive portion corresponding to a shape of the second portion, and a third emissive portion corresponding to a shape of the third portion.

In an embodiment, the second portion and the third portion may be spaced from each other and may face each other in the first direction.

In an embodiment, the first portion, the second portion, and the third portion may have a one-body shape.

In an embodiment, the first anode may include a first portion extending in the second direction, a second portion extending from the first portion in the first direction, and a third portion extending from the first portion in the first direction.

In an embodiment, the second portion and the third portion may be spaced from each other and may face each other in the second direction.

In an embodiment, the plurality of data lines may be located at a same layer as that of the connecting electrode.

According to one or more embodiments of the present disclosure, an electronic device includes: a display panel including a circuit layer including a plurality of data lines, and a light emitting element layer on the circuit layer. The light emitting element layer includes: a first anode on the circuit layer; a first emissive layer on the first anode, and configured to provide a blue light; a second anode on the circuit layer; a second emissive layer on the second anode, and configured to provide a green light; and a cathode on the first emissive layer and the second emissive layer. The plurality of data lines includes: a first data line extending in a first direction; and a second data line spaced from the first data line in a second direction crossing the first direction. The first data line and the second data line overlap with the first anode, and do not overlap with the second anode in a plan view.

In an embodiment, the first anode may include a first portion extending in the first direction, a second portion extending from the first portion in the second direction, and a third portion extending from the first portion in the second direction.

In an embodiment, the first data line and the second data line may overlap with the first portion in a plan view.

In an embodiment, the first emissive layer may include a first emissive portion corresponding to a shape of the first portion, a second emissive portion corresponding to a shape of the second portion, and a third emissive portion corresponding to a shape of the third portion.

In an embodiment, the first anode may include a first portion extending in the second direction, a second portion extending from the first portion in the first direction, and a third portion extending from the first portion in the first direction.

In an embodiment, the first portion and the third portion may be spaced from each other and may face each other in the second direction.

In an embodiment, the first data line may be configured to receive a first data signal, and the second data line may be configured to receive a second data signal different from the first data signal.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of an electronic device according to an embodiment of the present disclosure.

FIG. 2 illustrates various schematic views of some electronic devices according to some embodiments of the present disclosure.

FIG. 3 is a perspective view of an electronic device according to an embodiment of the present disclosure.

FIG. 4 is a sectional view of an electronic device according to an embodiment of the present disclosure.

FIG. 5 is a block diagram of an electronic device according to an embodiment of the present disclosure.

FIG. 6 is a sectional view of a display panel taken along the line I-I′ illustrated in FIG. 5 according to an embodiment of the present disclosure.

FIG. 7 is an equivalent circuit diagram illustrating a pixel according to an embodiment of the present disclosure.

FIG. 8 is a plan view illustrating a portion of a display panel according to an embodiment of the present disclosure.

FIG. 9 is a plan view illustrating a portion of a circuit layer according to an embodiment of the present disclosure.

FIG. 10 is a plan view illustrating a portion of a circuit layer according to an embodiment of the present disclosure.

FIG. 11 is a plan view illustrating a portion of a circuit layer according to an embodiment of the present disclosure.

FIG. 12 is a plan view illustrating a portion of a circuit layer according to an embodiment of the present disclosure.

FIG. 13 is a plan view illustrating a portion of a circuit layer according to an embodiment of the present disclosure.

FIG. 14 is a plan view illustrating a portion of a light emitting element layer according to an embodiment of the present disclosure.

FIG. 15 is a plan view illustrating a portion of a display panel according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein (e.g., the various modules and/or units) may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

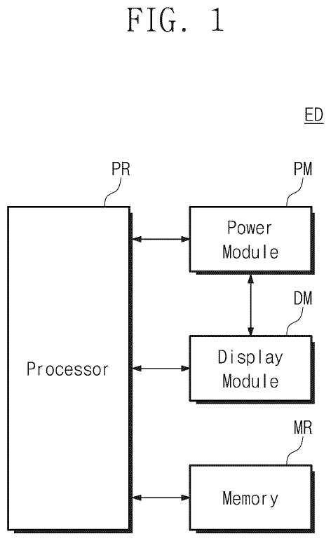

FIG. 1 is a block diagram of an electronic device according to an embodiment of the present disclosure.

The electronic device according to some embodiments of the present disclosure may be provided in various suitable forms. The electronic device may include various modules or devices having various functions.

Referring to FIG. 1, the electronic device ED according to an embodiment may include a display module (e.g., a display or a touch-display) DM, a processor PR, a memory MR, and a power module (e.g., a power supply) PM.

The processor PR may include at least one of a central processing unit (CPU), an application processor (AP), a graphic processing unit (GPU), a communication processor (CP), an image signal processor (ISP), and/or a controller. The processor PR may control the power module PM, the display module DM, and the memory MR.

Data information used for operations of the processor PR or the display module DM may be stored in the memory MR. When the processor PR executes an application stored in the memory MR, an image data signal and/or an input control signal may be transferred to the display module DM, and the display module DM may process the provided signal to output image information through a display screen.

The power module PM may include a power supply module, such as a power adaptor or a battery device, and a power conversion module that converts power supplied by the power supply module to generate power used for operations of the electronic device ED.

The display module DM may operate in response to an electrical signal. Some separate modules functionally included in one module may be included in the display module DM, and the others may be provided in the electronic device ED separately from the display module DM.

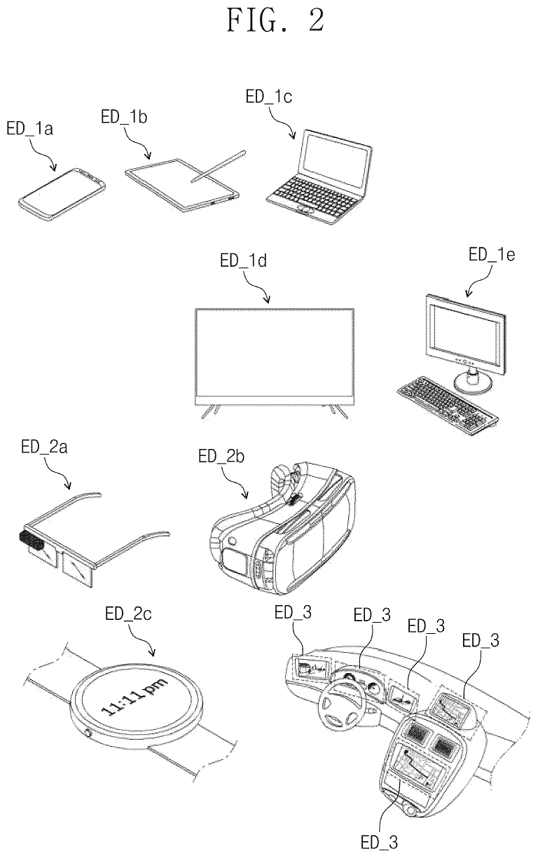

FIG. 2 illustrates various schematic views of some electronic devices according to some embodiments of the present disclosure.

Referring to FIG. 2, the electronic devices according to some embodiments may include not only electronic devices for displaying an image, such as a smart phone ED_1a, a tablet PC ED_1b, a laptop computer ED_1c, a TV ED_1d, and a desk monitor ED_1e, but may also include wearable electronic devices including a display module (e.g., a display or a touch-display), such as smart glasses ED_2a, a head mounted display ED_2b, and a smart watch ED_2c.

The electronic devices according to some embodiments may be equipped in a transport device, such as a vehicle, to provide various pieces of information to a user through an image. For example, the electronic device according to some embodiments of the present disclosure may be provided in a vehicle electronic device ED_3 including a display module (e.g., a display or a touch-display), such as a center information display (CID) disposed on an instrument panel, a center fascia, or a dashboard of a vehicle, or a room mirror display.

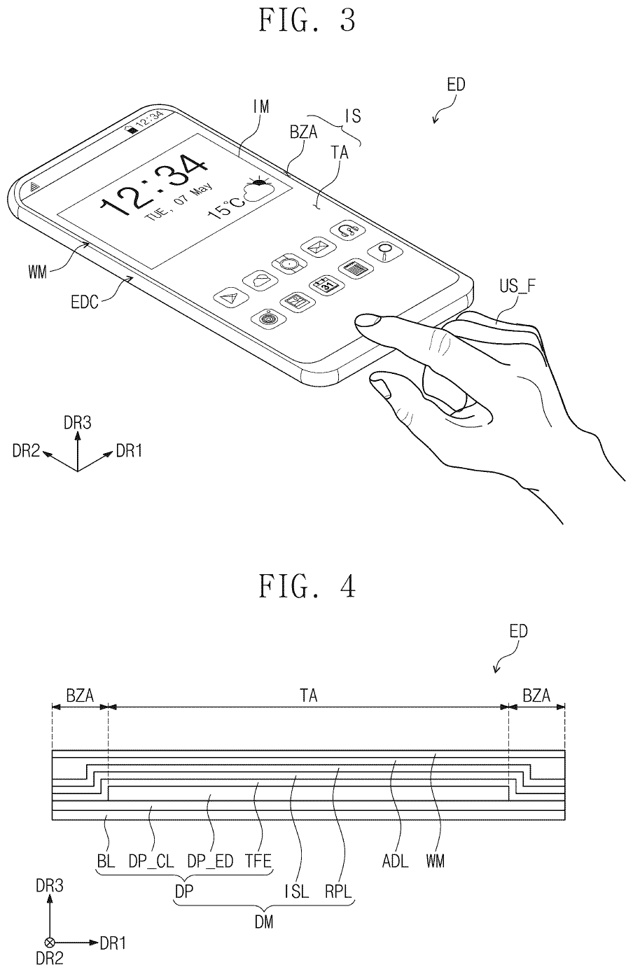

FIG. 3 is a perspective view of an electronic device according to an embodiment of the present disclosure. FIG. 4 is a sectional view of the electronic device according to an embodiment of the present disclosure.

Referring to FIGS. 3 and 4, the electronic device ED according to an embodiment of the present disclosure may have a rectangular shape having short sides parallel to or substantially parallel to a first direction DR1, and long sides parallel to or substantially parallel to a second direction DR2 crossing the first direction DR1. However, the present disclosure is not limited thereto, and the electronic device ED may have various suitable shapes, such as a circular shape or another polygonal shape.

The electronic device ED may be a device that is activated in response to an electrical signal. The electronic device ED may be applied to various kinds of electronic devices. For example, the electronic device ED may be applied to various suitable electronic devices, such as a smart watch, a tablet computer, a notebook computer, a computer, and a smart television.

Hereinafter, a normal direction perpendicular to or substantially perpendicular to a plane defined by the first direction DR1 and the second direction DR2 is defined as a third direction DR3. The expressions “when viewed from above the plane” and “in a plan view” as used herein may refer to a view of an object portion in the third direction DR3.

The upper surface of the electronic device ED may be defined as a display surface IS, and may be parallel to or substantially parallel to the plane defined by the first direction DR1 and the second direction DR2. Images IM generated by the electronic device ED may be provided to a user through the display surface IS.

The display surface IS may be divided into a transmissive area TA and a bezel area BZA. The transmissive area TA may be an area where the images IM are displayed. The user visually recognizes the images IM through the transmissive area TA. In the present embodiment, the transmissive area TA is illustrated as having a rounded rectangular shape. However, the present disclosure is not limited thereto, and the transmissive area TA may have various suitable shapes and is not limited to any particular shape.

The bezel area BZA is adjacent to the transmissive area TA. The bezel area BZA may have a desired color (e.g., a certain or predetermined color). The bezel area BZA may surround (e.g., around a periphery of) the transmissive area TA. Accordingly, the shape of the transmissive area TA may be defined or substantially defined by the bezel area BZA. However, the present disclosure is not limited thereto, and the bezel area BZA may be disposed adjacent to one side (e.g., only one side) of the transmissive area TA or may be omitted as needed or desired.

The electronic device ED may sense an external input applied from the outside. The external input may include various suitable kinds of inputs provided from outside the electronic device ED. For example, the external input may include not only a contact by a body part, such as the user's hand US_F, or a contact by a separate device (e.g., an active pen or a digitizer), but may also include an external input (e.g., hovering) that is applied in proximity to the electronic device ED, or applied adjacent to the electronic device ED at a suitable distance (e.g., a certain or predetermined distance). In addition, the external input may have various suitable forms, such as force, pressure, temperature, and light.

The electronic device ED may include a window WM, a display module (e.g., a display or a touch-display) DM, and a housing EDC. In the present embodiment, the window WM and the housing EDC are coupled with each other to form the exterior of the electronic device ED.

The front surface of the window WM defines the display surface IS of the electronic device ED. The window WM may include an optically clear insulating material. For example, the window WM may include glass or a plastic. The window WM may have a multi-layered structure or a single-layer structure. For example, the window WM may include a plurality of plastic films coupled to each other through an adhesive, or may include a glass substrate and a plastic film coupled to each other through an adhesive.

The display module DM may include a display panel DP and an input sensor ISL. The display panel DP may display an image in response to an electrical signal. The input sensor ISL may sense an external input applied from the outside. The external input may be provided in various suitable forms. The input sensor ISL may detect the external inputs described above.

The display panel DP according to an embodiment of the present disclosure may be an emissive display panel, but is not particularly limited. For example, the display panel DP may be an organic light emitting display panel, an inorganic light emitting display panel, or a quantum-dot light emitting display panel. An emissive layer of the organic light emitting display panel may include an organic luminescent material, and an emissive layer of the inorganic light emitting display panel may include an inorganic luminescent material. An emissive layer of the quantum-dot light emitting display panel may include a quantum dot and/or a quantum rod. Hereinafter, for convenience of illustration, the display panel DP may be described in more detail in the context of an organic light emitting display panel.

The display panel DP includes a base layer BL, a circuit layer DP_CL, a light emitting element layer DP_ED, and an encapsulation layer TFE. The display panel DP according to some embodiments of the present disclosure may be a flexible display panel. However, the present disclosure is not limited thereto. For example, the display panel DP may be a foldable display panel that may be folded about a folding axis, or may be a rigid display panel.

The base layer BL may include a synthetic resin layer. The synthetic resin layer may be a polyimide-based resin layer, but the material thereof is not particularly limited. In addition, the base layer BL may include a glass substrate, a metal substrate, or an organic/inorganic composite substrate.

The circuit layer DP_CL is disposed on the base layer BL. The circuit layer DP_CL is disposed between the base layer BL and the light emitting element layer DP_ED. The circuit layer DP_CL includes at least one insulating layer and a circuit element. Hereinafter, the insulating layer included in the circuit layer DP_CL is referred to as an intermediate insulating layer. The intermediate insulating layer includes at least one intermediate inorganic layer and at least one intermediate organic layer. The circuit element may include a pixel driving circuit included in each of a plurality of pixels for displaying an image, and a sensor driving circuit included in each of a plurality of sensors for recognizing external information. The external information may be biometric information. In an embodiment of the present disclosure, the sensors may include a fingerprint sensor, a proximity sensor, an iris recognition sensor, a blood pressure measurement sensor, or an illuminance sensor. In addition, the sensors may include an optical sensor that recognizes biometric information in an optical manner. The circuit layer DP_CL may further include signal lines connected to the pixel driving circuit and/or the sensor driving circuit.

The light emitting element layer DP_ED may include a light emitting element included in each of the pixels, and a light receiving element included in each of the sensors. In an embodiment of the present disclosure, the light receiving element may be a photo diode. The light receiving element may be a sensor that senses light reflected by the user's fingerprint or reacts to light.

The encapsulation layer TFE seals the light emitting element layer DP_ED. The encapsulation layer TFE may include at least one organic layer and at least one inorganic layer. The inorganic layer may include an inorganic material, and may protect the light emitting element layer DP_ED from moisture/oxygen. The inorganic layer may include a silicon nitride layer, a silicon oxy nitride layer, a silicon oxide layer, a titanium oxide layer, or an aluminum oxide layer, but the present disclosure is not particularly limited thereto. The organic layer may include an organic material, and may protect the light emitting element layer DP_ED from foreign matter, such as dust particles.

The input sensor ISL may be formed on the display panel DP. The input sensor ISL may be directly disposed on the encapsulation layer TFE. According to an embodiment of the present disclosure, the input sensor ISL may be formed on the display panel DP by a continuous process. In other words, when the input sensor ISL is directly disposed on the display panel DP, an adhesive film is not disposed between the input sensor ISL and the encapsulation layer TFE. In another embodiment, an adhesive film may be disposed between the input sensor ISL and the display panel DP. In this case, the input sensor ISL may not be manufactured with the display panel DP by a continuous process, and may be manufactured separately from the display panel DP and then fixed to the upper surface of the display panel DP by an adhesive film.

The input sensor ISL may sense an external input (e.g., the user's touch), may change the external input to a suitable input signal (e.g., a certain or predetermined input signal), and may provide the input signal to the display panel DP. The input sensor ISL may include a plurality of sensing electrodes for sensing the external input. The sensing electrodes may sense the external input in a capacitive manner. The display panel DP may receive the input signal from the input sensor ISL, and may generate an image corresponding to the input signal.

The display module DM may further include an anti-reflective layer RPL. The anti-reflective layer RPL may decrease a reflectance of external light incident toward the display panel DP from above the electronic device ED. The external light may not be visible to the user due to the anti-reflective layer RPL. In an embodiment of the present disclosure, the anti-reflective layer RPL may be disposed on the input sensor ISL. However, the present disclosure is not limited thereto. The anti-reflective layer RPL may be disposed between the display panel DP and the input sensor ISL. The anti-reflective layer RPL may include a plurality of color filters disposed to correspond to the pixels, respectively. The color filters may filter the external light in the same colors as those of the pixels. In this case, the external light may not be visible to the user. However, the present disclosure is not limited thereto, and the anti-reflective layer RPL may include a phase retarder and/or a polarizer to decrease the reflectance of the external light.

The electronic device ED according to an embodiment of the present disclosure may further include an adhesive layer ADL. The window WM may be attached to the anti-reflective layer RPL by the adhesive layer ADL. The adhesive layer ADL may include an optically clear adhesive, an optically clear adhesive resin, or a pressure sensitive adhesive (PSA).

The housing EDC is coupled with the window WM. The housing EDC is coupled with the window WM to provide an inner space. The display module DM may be accommodated in the inner space. The housing EDC may include a suitable material having a relatively high rigidity. For example, the housing EDC may include a plurality of frames and/or plates made of glass, a plastic, a metal, or a suitable combination thereof. The housing EDC may stably protect the components of the electronic device ED accommodated in the inner space from an external impact. In some embodiments, a battery module that supplies power used for the overall operations of the electronic device ED may be disposed between the display module DM and the housing EDC.

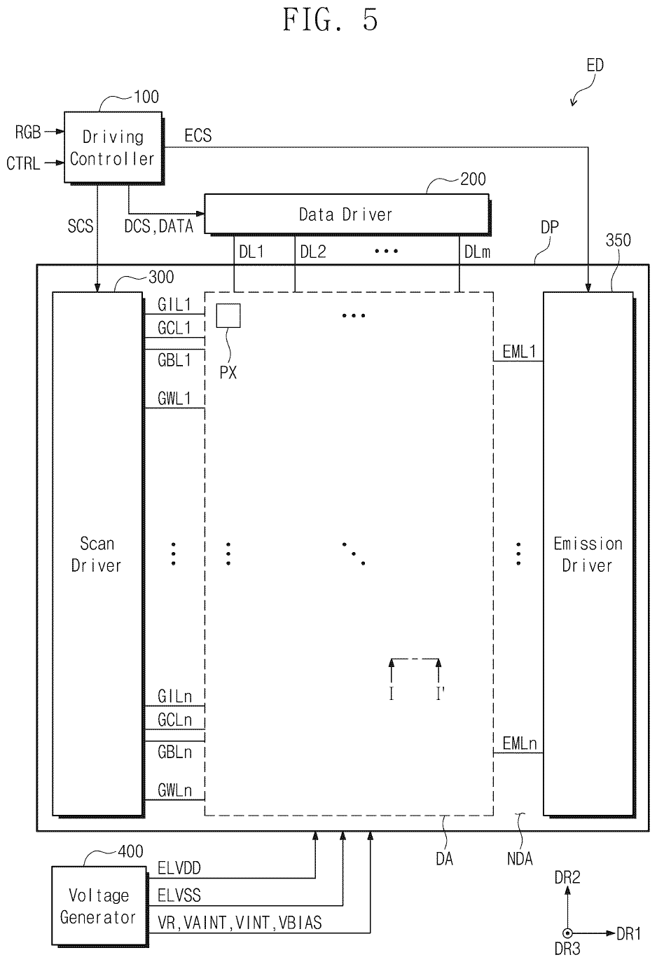

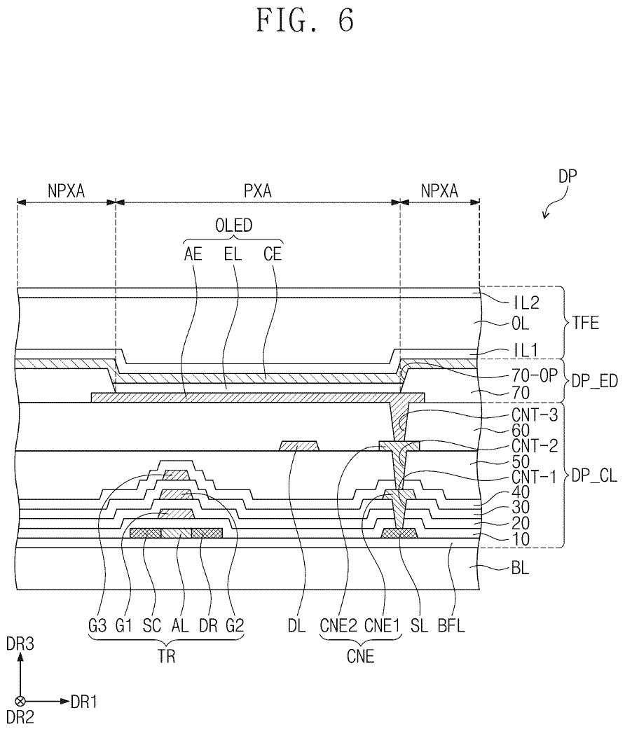

FIG. 5 is a block diagram of the electronic device according to an embodiment of the present disclosure.

Referring to FIG. 5, the electronic device ED includes the display panel DP, a panel driver, and a driving controller 100. In an embodiment of the present disclosure, the panel driver includes a data driver 200, a scan driver 300, an emission driver 350, and a voltage generator 400.

The driving controller 100 receives an image signal RGB and a control signal CTRL. The driving controller 100 generates image data DATA by converting a data format of the image signal RGB according to a specification of an interface with the data driver 200. The driving controller 100 outputs a first control signal SCS, a second control signal ECS, and a third control signal DCS.

The data driver 200 receives the third control signal DCS and the image data DATA from the driving controller 100. The data driver 200 converts the image data DATA into data signals, and outputs the data signals to a plurality of data lines DL1 to DLm described in more detail below. The data signals may be analog voltages corresponding to grayscale values or levels of the image data DATA.

The scan driver 300 receives the first control signal SCS from the driving controller 100. The scan driver 300 may output scan signals to scan lines in response to the first control signal SCS.

The voltage generator 400 generates voltages used for operations of the display panel DP. In the present embodiment, the voltage generator 400 may generate a first voltage ELVDD, a second voltage ELVSS, a reference voltage VR, a first initialization voltage VINT, a second initialization voltage VAINT, and a bias voltage VBIAS.

The display panel DP may include a display area DA corresponding to the transmissive area TA (e.g., refer to FIG. 3), and a non-display area NDA corresponding to the bezel area BZA.

The display panel DP may include a plurality of pixels PX disposed in the display area DA. The display panel DP further includes initialization scan lines GIL1 to GILn, compensation scan lines GCL1 to GCLn, write scan lines GWL1 to GWLn, bias scan lines GBL1 to GBLn, emission lines EML1 to EMLn, and the data lines DL1 to DLm, where n and m are natural numbers greater than or equal to 1. The initialization scan lines GIL1 to GILn, the compensation scan lines GCL1 to GCLn, the write scan lines GWL1 to GWLn, the bias scan lines GBL1 to GBLn, and the emission lines EML1 to EMLn extend in the first direction DR1. The initialization scan lines GIL1 to GILn, the compensation scan lines GCL1 to GCLn, the write scan lines GWL1 to GWLn, the bias scan lines GBL1 to GBLn, and the emission lines EML1 to EMLn are spaced apart from one another along the second direction DR2. The data lines DL1 to DLm extend in the second direction DR2, and are spaced apart from one another along the first direction DR1.

The plurality of pixels PX are electrically connected to the initialization scan lines GIL1 to GILn, the compensation scan lines GCL1 to GCLn, the write scan lines GWL1 to GWLn, the bias scan lines GBL1 to GBLn, the emission lines EML1 to EMLn, and the data lines DL1 to DLm. For example, each of the plurality of pixels PX may be electrically connected to four scan lines. However, the number of scan lines connected to each pixel PX is not limited thereto, and may be variously modified as needed or desired.

The scan driver 300 may be disposed in the non-display area NDA of the display panel DP. The scan driver 300 receives the first control signal SCS from the driving controller 100. In response to the first control signal SCS, the scan driver 300 outputs initialization scan signals to the initialization scan lines GIL1 to GILn, and outputs compensation scan signals to the compensation scan lines GCL1 to GCLn. In addition, in response to the first control signal SCS, the scan driver 300 may output write scan signals to the write scan lines GWL1 to GWLn, and may output bias scan signals to the bias scan lines GBL1 to GBLn. In another embodiment, the scan driver 300 may include a first scan driver and a second scan driver. The first scan driver may output the initialization scan signals and the compensation scan signals, and the second scan driver may output the write scan signals and the bias scan signals.

The emission driver 350 may be disposed in the non-display area NDA of the display panel DP. The emission driver 350 receives the second control signal ECS from the driving controller 100. In response to the second control signal ECS, the emission driver 350 may output emission control signals to the emission lines EML1 to EMLn. In another embodiment, the scan driver 300 may be connected to the emission lines EML1 to EMLn. In this case, the emission driver 350 may be omitted, and the scan driver 300 may output the emission control signals to the emission lines EML1 to EMLn.

FIG. 6 is a sectional view of the display panel taken along the line I-I′ illustrated in FIG. 5 according to an embodiment of the present disclosure. In FIG. 6, the same or substantially the same components as those described above with reference to FIG. 4 are assigned with the same reference numerals, and thus, redundant description thereof may not be repeated.

Referring to FIG. 6, the display panel DP may include the base layer BL, the circuit layer DP_CL, the light emitting element layer DP_ED, and the encapsulation layer TFE.

At least one buffer layer BFL may be formed on the upper surface of the base layer BL. The buffer layer BFL may improve a coupling force between the base layer BL and a semiconductor pattern SC, AL, DR, and SL. The buffer layer BFL may be formed of multiple layers. In another embodiment, the display panel DP may further include a barrier layer. The buffer layer BFL may include at least one of silicon oxide, silicon nitride, and/or silicon oxy nitride. For example, the buffer layer BFL may include a structure in which silicon oxide layers and silicon nitride layers are alternately stacked one above another.

The semiconductor pattern SC, AL, DR, and SL may be disposed on the buffer layer BFL. The semiconductor pattern SC, AL, DR, and SL may include poly silicon. However, the present disclosure is not limited thereto, and the semiconductor pattern SC, AL, DR, and SL may include amorphous silicon, a low-temperature polycrystalline silicon, or an oxide semiconductor.

FIG. 6 illustrates a part of the semiconductor pattern SC, AL, DR, and SL, and semiconductor patterns may be further disposed in other areas. The semiconductor pattern SC, AL, DR, and SL may be arranged across the pixels according to a desired rule (e.g., a specific or predetermined rule). The semiconductor pattern SC, AL, DR, and SL may have different electrical properties depending on whether doping is performed or not. The semiconductor pattern SC, AL, DR, and SL may include first areas SC, DR, and SL having a higher conductivity, and a second area AL having a lower conductivity. The first areas SC, DR, and SL may be doped with an N-type dopant or a P-type dopant. A P-type transistor may include a doped area doped with a P-type dopant, and an N-type transistor may include a doped area doped with an N-type dopant. The second area AL may be a non-doped area, or may be an area that is more lightly doped than those of the first areas SC, DR, and SL.

The first areas SC, DR, and SL may have a higher conductivity than that of the second area AL, and may serve or substantially serve as an electrode or a signal line. The second area AL may correspond to or substantially correspond to an active area (e.g., a channel) AL of a transistor TR. In other words, one portion AL of the semiconductor pattern SC, AL, DR, and SL may be the active area AL of the transistor TR, another portion SC or DR may be a source area SC or a drain area DR of the transistor TR, and another portion SL may be a connecting electrode or connecting signal line SL.

Each of the pixels may have an equivalent circuit including a plurality of transistors, at least one capacitor, and at least one light emitting element, but the equivalent circuit diagram of the pixel may be modified in various suitable forms. FIG. 6 illustrates one transistor TR and one light emitting element OLED included in the pixel.

The source area SC, the active area AL, and the drain area DR of the transistor TR may be formed from the semiconductor pattern SC, AL, DR, and SL. The source area SC and the drain area DR may extend from the active area AL in opposite directions from each other on a cross-section. A portion of the connecting signal line SL formed from the semiconductor pattern SC, AL, DR, and SL is illustrated in FIG. 6. In another view, the connecting signal line SL may be connected to the drain area DR of the transistor TR when viewed from above the plane (e.g., in a plan view).

A first insulating layer 10 may be disposed on the buffer layer BFL. The first insulating layer 10 may commonly overlap with the plurality of pixels, and may cover the semiconductor pattern SC, AL, DR, and SL. The first insulating layer 10 may be an inorganic layer and/or an organic layer, and may have a single-layer structure or a multi-layered structure. The first insulating layer 10 may include at least one of aluminum oxide, titanium oxide, silicon oxide, silicon nitride, silicon oxy nitride, zirconium oxide, and/or hafnium oxide. In the present embodiment, the first insulating layer 10 may be a single silicon oxide layer. Not only the first insulating layer 10, but also insulating layers of the circuit layer DP_CL to be described in more detail below, may be inorganic layers and/or organic layers, and may have a single-layer structure or a multi-layered structure. The inorganic layers may include at least one of the aforementioned inorganic materials, but are not limited thereto.

A first gate G1 of the transistor TR is disposed on the first insulating layer 10. The first gate G1 may be a portion of a metal pattern. The first gate G1 overlaps with the active area AL. In a process of doping or reducing the semiconductor pattern SC, AL, DR, and SL, the first gate G1 may function as a mask.

A second insulating layer 20 may be disposed on the first insulating layer 10, and may cover the first gate G1. The second insulating layer 20 may commonly overlap with the pixels. The second insulating layer 20 may be an inorganic layer and/or an organic layer, and may have a single-layer structure or a multi-layered structure. The second insulating layer 20 may include at least one of silicon oxide, silicon nitride, and/or silicon oxy nitride. In the present embodiment, the second insulating layer 20 may have a multi-layered structure including a silicon oxide layer and a silicon nitride layer.

A second gate G2 of the transistor TR is disposed on the second insulating layer 20. The second gate G2 may be a portion of a metal pattern. The second gate G2 overlaps with the active area AL.

A third insulating layer 30 may be disposed on the second insulating layer 20. The third insulating layer 30 may cover the second gate G2. The third insulating layer 30 may have a single-layer structure or a multi-layered structure. For example, the third insulating layer 30 may have a multi-layered structure including a silicon oxide layer and a silicon nitride layer.

A third gate G3 of the transistor TR is disposed on the third insulating layer 30. The third gate G3 may be a portion of a metal pattern. The third gate G3 overlaps with the active area AL.

A first connecting electrode CNE1 may be disposed on the third insulating layer 30. The first connecting electrode CNE1 may be connected to the connecting signal line SL through a contact hole CNT-1 that penetrates the first insulating layer 10, the second insulating layer 20, and the third insulating layer 30.

A fourth insulating layer 40 may be disposed on the third insulating layer 30. The fourth insulating layer 40 may be a single silicon oxide layer. A fifth insulating layer 50 may be disposed on the fourth insulating layer 40. The fifth insulating layer 50 may be an organic layer.

A second connecting electrode CNE2 may be disposed on the fifth insulating layer 50. The second connecting electrode CNE2 may be connected to the first connecting electrode CNE1 through a contact hole CNT-2 that penetrates the fourth insulating layer 40 and the fifth insulating layer 50.

A data line DL may be disposed on the fifth insulating layer 50. The data line DL may include the same material as that of the second connecting electrode CNE2.

The data line DL and the second connecting electrode CNE2 may be formed in the same layer as each other. The data line DL and the second connecting electrode CNE2 may be formed through the same process as each other, and thus, may have the same material and the same stacked structure as each other. As used herein, components that are disposed at (e.g., in or on) the same layer and include the same material as each other may be understood as being formed through the same process as each other.

A sixth insulating layer 60 may be disposed on the fifth insulating layer 50, and may cover the second connecting electrode CNE2 and the data line DL. The sixth insulating layer 60 may be an organic layer.

The light emitting element layer DP_ED may be disposed on the circuit layer DP_CL. The light emitting element layer DP_ED may include the light emitting element OLED. For example, the light emitting element layer DP_ED may include an organic luminescent material, an inorganic luminescent material, an organic-inorganic luminescent material, a quantum dot, a quantum rod, a micro-LED, or a nano-LED. Hereinafter, for convenience of illustration, the light emitting element OLED may be described in more detail in the context of an organic light emitting element. However, the present disclosure is not particularly limited thereto.

The light emitting element OLED may include an anode AE, an emissive layer EL, and a cathode CE.

The anode AE may be disposed on the sixth insulating layer 60. The anode AE may be connected to the second connecting electrode CNE2 through a contact hole CNT-3 that penetrates the sixth insulating layer 60. For example, the anode AE may be connected with the connecting signal line SL through a connecting electrode CNE including the first connecting electrode CNE1 and the second connecting electrode CNE2.

A pixel defining layer 70 may be disposed on the sixth insulating layer 60, and may cover a portion of the anode AE. An opening 70-OP is defined in (e.g., penetrates) the pixel defining layer 70. The opening 70-OP of the pixel defining layer 70 exposes at least a portion of the anode AE.

The display area DA (e.g., refer to FIG. 5) may include an emissive area PXA, and a non-emissive area NPXA adjacent to the emissive area PXA. The non-emissive area NPXA may surround (e.g., around a periphery of) the emissive area PXA. In the present embodiment, the emissive area PXA is defined to correspond to a partial area of the anode AE exposed by the opening 70-OP.

The emissive layer EL may be disposed on the anode AE. The emissive layer EL may be disposed in the area corresponding to the opening 70-OP. Although FIG. 6 illustrates an example in which the emissive layer EL is disposed in the opening 70-OP, the present disclosure is not particularly limited thereto. For example, the emissive layer EL may extend to cover the side surface of the pixel defining layer 70 that defines the opening 70-OP and a portion of the upper surface of the pixel defining layer 70.

In an embodiment of the present disclosure, the emissive layer EL may be separately formed in each of the pixels. Each of the emissive layers EL may emit at least one of a blue light, a red light, or a green light.

The cathode CE may be disposed on the emissive layer EL. The cathode CE may have a one-body shape (e.g., an integrated shape), and may be commonly included in the plurality of pixels.

In an embodiment of the present disclosure, a hole control layer may be disposed between the anode AE and the emissive layer EL. The hole control layer may be commonly disposed in the emissive area PXA and the non-emissive area NPXA. The hole control layer may include a hole transport layer, and may further include a hole injection layer as needed or desired. An electron control layer may be disposed between the emissive layer EL and the cathode CE. The electron control layer may include an electron transport layer, and may further include an electron injection layer as needed or desired. The hole control layer and the electron control layer may be commonly formed in the plurality of pixels using an open mask or an ink-jet process.

The encapsulation layer TFE may be disposed on the light emitting element layer DP_ED. The encapsulation layer TFE may include a first inorganic encapsulation layer IL1, an organic encapsulation layer OL, and a second inorganic encapsulation layer IL2 sequentially stacked one above another. However, the layers constituting the encapsulation layer TFE are not necessarily limited thereto. The inorganic encapsulation layers IL1 and IL2 may include a silicon nitride layer, a silicon oxy nitride layer, a silicon oxide layer, a titanium oxide layer, or an aluminum oxide layer. The inorganic encapsulation layers IL1 and IL2 may protect the light emitting element layer DP_ED from moisture and oxygen. Each of the inorganic encapsulation layers IL1 and IL2 may have a multi-layered structure. The organic encapsulation layer OL may include an acrylic organic layer, but is not limited thereto. The organic encapsulation layer OL may protect the light emitting element layer DP_ED from foreign matter, such as dust particles.

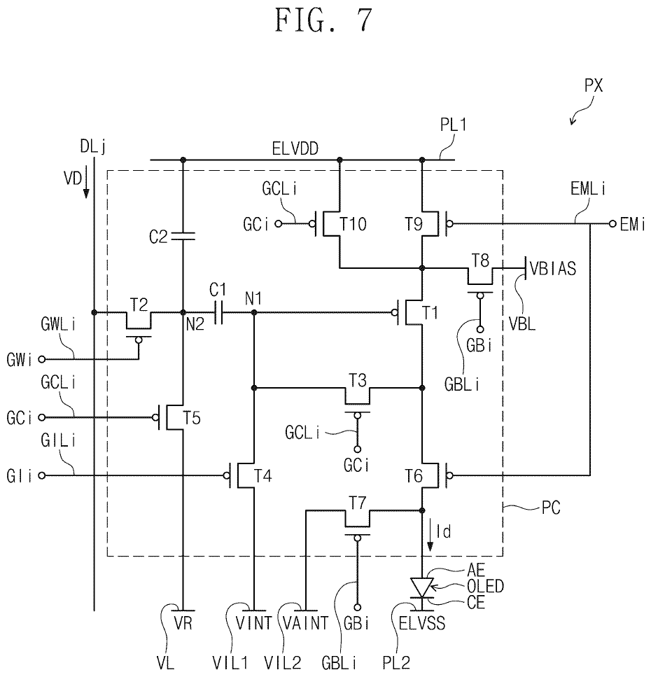

FIG. 7 is an equivalent circuit diagram illustrating a pixel according to an embodiment of the present disclosure.

Referring to FIG. 7, the pixel PX may include a pixel circuit PC, and a light emitting element OLED connected to the pixel circuit PC. The pixel PX illustrated in FIG. 7 may be a pixel disposed in an i-th row and a j-th column, where i and j are natural numbers. The row may correspond to the first direction DR1, and the column may correspond to the second direction DR2. Each of the plurality of pixels PX illustrated in FIG. 5 may have a configuration that is the same or substantially the same as that of the pixel PX illustrated in FIG. 7.

The pixel circuit PC may drive the light emitting element OLED. The light emitting element OLED may be defined as an organic light emitting element. The light emitting element OLED may include an anode AE and a cathode CE.

The pixel circuit PC may include a plurality of transistors T1 to T10 and a plurality of capacitors C1 and C2. The transistors T1 to T10 and the capacitors C1 and C2 may control an amount of current flowing through the light emitting element OLED. The light emitting element OLED may generate light having a desired luminance (e.g., a certain or predetermined luminance) depending on the amount of current supplied thereto.

The pixel PX may be connected to the i-th write scan line GWLi, the i-th compensation scan line GCLi, the i-th initialization scan line GILi, the i-th bias scan line GBLi, the i-th emission line EMLi, the j-th data line DLj, a first initialization line VIL1, a second initialization line VIL2, a reference line VL, a bias line VBL, a first power line PL1, and a second power line PL2.

The i-th write scan line GWLi may receive the i-th write scan signal GWi, and the i-th compensation scan line GCLi may receive the i-th compensation scan signal GCi. The i-th initialization scan line GILi may receive the i-th initialization scan signal Gli, and the i-th bias scan line GBLi may receive the i-th bias scan signal GBi. The i-th emission line EMLi may receive the i-th emission signal EMi.

The first initialization line VIL1 may receive the first initialization voltage VINT, and the second initialization line VIL2 may receive the second initialization voltage VAINT. The bias line VBL may receive the bias voltage VBIAS, and the reference line VL may receive the reference voltage VR. The first power line PL1 may receive the first voltage ELVDD, and the second power line PL2 may receive the second voltage ELVSS.

Each of the transistors T1 to T10 may include a source electrode, a drain electrode, and a gate electrode. Hereinafter, in FIG. 7, for convenience of illustration, one of the source electrode or the drain electrode is defined as a first electrode, and the other is defined as a second electrode. In addition, the gate electrode is defined as a control electrode.

The transistors T1 to T10 may include the first to tenth transistors T1 to T10. The first to tenth transistors T1 to T10 may be PMOS transistors. However, the present disclosure is not limited thereto, and the first to tenth transistors T1 to T10 may be NMOS transistors. The capacitors C1 and C2 may include the first capacitor C1 and the second capacitor C2.

The transistors T1 to T10 and the capacitors C1 and C2 may be directly or indirectly connected to the lines GWLi, GCLi, GILi, GBLi, EMLi, DLj, VIL1, VIL2, VL, VBL, PL1, and PL2 and the light emitting element OLED.

For example, the second transistor T2 may be directly connected to the j-th data line DLj and the i-th write scan line GWLi, and the first capacitor C1 may be indirectly connected to the j-th data line DLj through the second transistor T2. The eighth transistor T8 may be directly connected to the bias line VBL, and the first transistor T1 may be indirectly connected to the bias line VBL through the eighth transistor T8. The sixth transistor T6 may be directly connected to the light emitting element OLED, and the first transistor T1 may be indirectly connected to the light emitting element OLED through the sixth transistor T6.

The first transistor T1 may be electrically connected between the light emitting element OLED and the first power line PL1, and may be switched by the voltage of a first node N1. In more detail, the first transistor T1 may be connected to the anode AE of the light emitting element OLED via the sixth transistor T6, and may be connected to the first power line PL1 via the ninth transistor T9. The first transistor T1 may be disposed between the sixth transistor T6 and the ninth transistor T9, and may be connected with the sixth transistor T6 and the ninth transistor T9.

The first transistor T1 may include the first electrode connected to the ninth transistor T9, the second electrode connected to the sixth transistor T6, and the control electrode connected to the first node N1. The first transistor T1 may control an amount of current flowing through the light emitting element OLED depending on the voltage of the first node N1 applied to the control electrode of the first transistor T1. The first transistor T1 may be defined as a driving transistor.

The second transistor T2 may be disposed between the j-th data line DLj and a second node N2, and may be connected to the j-th data line DLj and the second node N2. The second transistor T2 may be switched by the i-th write scan signal GWi. The second transistor T2 may include the first electrode connected to the j-th data line DLj, the second electrode connected to the second node N2, and the control electrode connected to the i-th write scan line GWLi. The second transistor T2 may be defined as a switching transistor.

The first capacitor C1 may be connected to the first node N1 and the second node N2. The first capacitor C1 may be connected to the control electrode of the first transistor T1 through the first node N1, and may be connected to the second electrode of the second transistor T2 through the second node N2. The first capacitor C1 may include a first electrode connected to the first node N1 and a second electrode connected to the second node N2.

The second transistor T2 may be turned on by the i-th write scan signal GWi applied through the i-th write scan line GWLi. The turned-on second transistor T2 may receive a data signal VD through the j-th data line DLj. The data signal VD may be provided to the first capacitor C1 through the turned-on second transistor T2.

The third transistor T3 may be connected to the second electrode of the first transistor T1 and the first node N1. The third transistor T3 may include the first electrode connected to the second electrode of the first transistor T1, the second electrode connected to the first node N1, and the control electrode connected to the i-th compensation scan line GCLi.

The third transistor T3 may be turned on by the i-th compensation scan signal GCi applied through the i-th compensation scan line GCLi, and may connect the second electrode of the first transistor T1 and the control electrode of the first transistor T1 to each other. When the third transistor T3 is turned on, the first transistor T1 and the third transistor T3 may be connected in the form of a diode (e.g., may be diode-connected). The third transistor T3 may be defined as a compensation transistor.

The fourth transistor T4 may be connected to the first node N1. The fourth transistor T4 may include the first electrode connected to the first node N1, the second electrode connected to the first initialization line VIL1, and the control electrode connected to the i-th initialization scan line GILi.

The fourth transistor T4 may be turned on by the i-th initialization scan signal Gli applied through the i-th initialization scan line GILi. The turned-on fourth transistor T4 may provide the first initialization voltage VINT applied through the first initialization line VIL1 to the first node N1. The fourth transistor T4 may be defined as a first initialization transistor.

The fifth transistor T5 may be disposed between the reference line VL and the second node N2, and may be connected to the reference line VL and the second node N2. The fifth transistor T5 may be switched by the i-th compensation scan signal GCi.

The fifth transistor T5 may include the first electrode connected to the second node N2, the second electrode connected to the reference line VL, and the control electrode connected to the i-th compensation scan line GCLi. The fifth transistor T5 may be turned on by the i-th compensation scan signal GCi applied through the i-th compensation scan line GCLi. The turned-on fifth transistor T5 may provide the reference voltage VR applied through the reference line VL to the second node N2. The fifth transistor T5 may be defined as a reference transistor.

The sixth transistor T6 may be connected to the first transistor T1 and the anode AE, and may be switched by the i-th emission signal EMi. The sixth transistor T6 may include the first electrode connected to the second electrode of the first transistor T1, the second electrode connected to the anode AE, and the control electrode connected to the i-th emission line EMLi.

The sixth transistor T6 may be turned on by the i-th emission signal EMi applied through the i-th emission line EMLi. The sixth transistor T6 may be defined as a first emission control transistor.

The seventh transistor T7 may be connected to the anode AE and the second initialization line VIL2, and may be switched by the i-th bias scan signal GBi. The seventh transistor T7 may include the first electrode connected to the anode AE, the second electrode connected to the second initialization line VIL2, and the control electrode connected to the i-th bias scan line GBLi.

The seventh transistor T7 may be turned on by the i-th bias scan signal GBi applied through the i-th bias scan line GBLi. The turned-on seventh transistor T7 may provide the second initialization voltage VAINT received through the second initialization line VIL2 to the anode AE of the light emitting element OLED. The seventh transistor T7 may be defined as a second initialization transistor.

The eighth transistor T8 may be connected to the first transistor T1 and the bias line VBL, and may be switched by the i-th bias scan signal GBi. The eighth transistor T8 may include the first electrode connected to the bias line VBL, the second electrode connected to the first electrode of the first transistor T1, and the control electrode connected to the i-th bias scan line GBLi.

The eighth transistor T8 may be turned on by the i-th bias scan signal GBi applied through the i-th bias scan line GBLi. The turned-on eighth transistor T8 may provide the bias voltage VBIAS received through the bias line VBL to the first electrode of the first transistor T1. The eighth transistor T8 may be defined as a bias transistor.

The ninth transistor T9 may be connected to the first power line PL1 and the first transistor T1, and may be switched by the i-th emission signal EMi. The ninth transistor T9 may include the first electrode connected to the first power line PL1, the second electrode connected to the first electrode of the first transistor T1, and the control electrode connected to the i-th emission line EMLi.

The ninth transistor T9 may be turned on by the i-th emission signal EMi applied through the i-th emission line EMLi. The ninth transistor T9 may be defined as a second emission control transistor. When the sixth transistor T6 and the ninth transistor T9 are turned on, the first voltage ELVDD may be provided to the light emitting element OLED, and a driving current Id may flow through the light emitting element OLED. Accordingly, the light emitting element OLED may emit light.

The tenth transistor T10 is connected between the first power line PL1 and the first transistor T1. The tenth transistor T10 may be switched by the i-th compensation scan signal GCi. The tenth transistor T10 may include the first electrode that receives the first voltage ELVDD through the first power line PL1, the second electrode electrically connected with the first electrode of the first transistor T1, and the control electrode connected to the i-th compensation scan line GCLi.

When the compensation scan signal GCi is supplied to the i-th compensation scan line GCLi, the tenth transistor T10 may be turned on to provide the first voltage ELVDD to the first electrode of the first transistor T1.

In the present embodiment, the control electrode of the tenth transistor T10 is illustrated as being connected to the same compensation scan line GCLi as that of the control electrode of the third transistor T3. Accordingly, the tenth transistor T10 and the third transistor T3 may be concurrently (e.g., simultaneously or substantially simultaneously) turned on with each other through the same compensation scan signal GCi. However, the present disclosure is not limited thereto, and the tenth transistor T10 and the third transistor T3 may be driven through independent scan signals and are not particularly limited thereto.

The second capacitor C2 may include a first electrode connected to the second node N2, and a second electrode connected to the first power line PL1.

The light emitting element OLED may be connected to the sixth transistor T6 among the transistors T1 to T9. The anode AE of the light emitting element OLED may be connected to the first power line PL1 through the sixth transistor T6, the first transistor T1, and the ninth transistor T9. The anode AE of the light emitting element OLED may receive the first voltage ELVDD through the sixth transistor T6, the first transistor T1, and the ninth transistor T9.

The cathode CE of the light emitting element OLED may be connected to the second power line PL2. The cathode CE of the light emitting element OLED may receive the second voltage ELVSS having a lower level than that of the first voltage ELVDD through the second power line PL2.

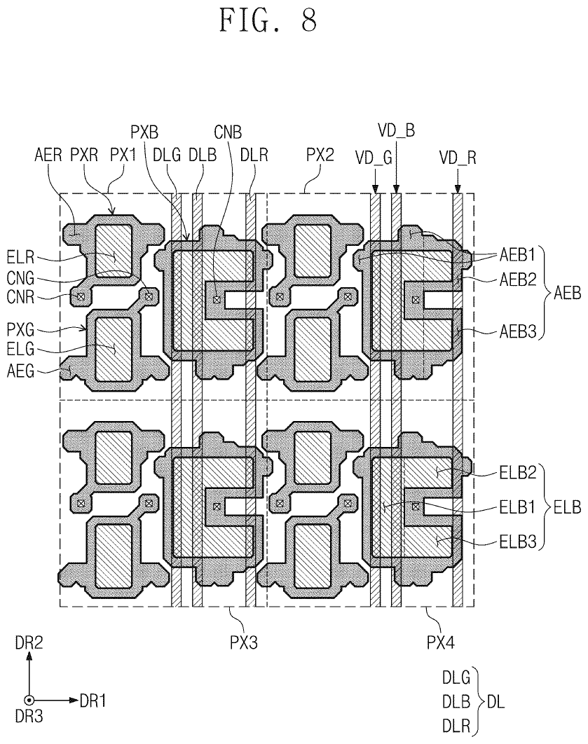

FIG. 8 is a plan view illustrating a portion of the display panel according to an embodiment of the present disclosure.

Each of a first sub-pixel PXR, a second sub-pixel PXG, and a third sub-pixel PXB illustrated in FIG. 8 may have the same circuit configuration as that of the equivalent circuit diagram of the pixel PX illustrated in FIG. 7.

Referring to FIGS. 5 to 8, the display panel DP may include the plurality of pixels PX and the data line DL. The data line DL may include a first data line DLR, a second data line DLG, and a third data line DLB.

The plurality of pixels PX may include a first pixel PX1, a second pixel PX2, a third pixel PX3, and a fourth pixel PX4. The second pixel PX2 may be spaced apart from the first pixel PX1 in the first direction DR1. The third pixel PX3 may be spaced apart from the first pixel PX1 in a direction opposite to the second direction DR2. The fourth pixel PX4 may be spaced apart from the second pixel PX2 in the direction opposite to the second direction DR2. The first to fourth pixels PX1 to PX4 may include the same or substantially the same components as each other.

The first pixel PX1 may include the first sub-pixel PXR, the second sub-pixel PXG, and the third sub-pixel PXB.

The second sub-pixel PXG may be spaced apart from the first sub-pixel PXR in the direction opposite to the second direction DR2.

The first sub-pixel PXR may be provided in a plurality, and the second sub-pixel PXG may be provided in a plurality. The plurality of first sub-pixels PXR and the plurality of second sub-pixels PXG may alternate with one another along the second direction DR2.

The third sub-pixel PXB may be spaced apart from the first sub-pixel PXR and the second sub-pixel PXG in the first direction DR1.

The third sub-pixel PXB may be provided in a plurality. The plurality of third sub-pixels PXB may be arranged along the second direction DR2.

A light emitting element OLED of the first sub-pixel PXR may include a first anode AER and a first emissive layer ELR. The first anode AER and the first emissive layer ELR may be disposed in the light emitting element layer DP_ED.

The first anode AER may be electrically connected to a pixel circuit PC of the first sub-pixel PXR through a first contact hole CNR. The first emissive layer ELR may be disposed on the first anode AER. The first emissive layer ELR may emit a red light.

The first anode AER may cover the first emissive layer ELR when viewed from above the plane (e.g., in a plan view. In other words, the area of the first anode AER may be greater than the area of the first emissive layer ELR when viewed from above the plane (e.g., in a plan view).

A light emitting element OLED of the second sub-pixel PXG may include a second anode AEG and a second emissive layer ELG. The second anode AEG and the second emissive layer ELG may be disposed in the light emitting element layer DP_ED.

The second anode AEG may be electrically connected to a pixel circuit PC of the second sub-pixel PXG through a second contact hole CNG. The second emissive layer ELG may be disposed on the second anode AEG. The second emissive layer ELG may emit a green light.

The second anode AEG may cover the second emissive layer ELG when viewed from above the plane (e.g., in a plan view). In other words, the area of the second anode AEG may be greater than the area of the second emissive layer ELG when viewed from above the plane (e.g., in a plan view).

The area of the second emissive layer ELG may be greater than the area of the first emissive layer ELR when viewed from above the plane (e.g., in a plan view). However, the present disclosure is not limited thereto, and the area of the first emissive layer ELR and the area of the second emissive layer ELG may be variously modified as needed or desired.

A light emitting element OLED of the third sub-pixel PXB may include a third anode AEB and a third emissive layer ELB. The third anode AEB and the third emissive layer ELB may be disposed in the light emitting element layer DP_ED.

The third anode AEB may be electrically connected to a pixel circuit PC of the third sub-pixel PXB through a third contact hole CNB. The third emissive layer ELB may be disposed on the third anode AEB. The third emissive layer ELB may emit a blue light.

The third anode AEB may cover the third emissive layer ELB when viewed from above the plane (e.g., in a plan view). In other words, the area of the third anode AEB may be greater than the area of the third emissive layer ELB when viewed from above the plane (e.g., in a plan view).

The area of the third emissive layer ELB may be greater than the area of the first emissive layer ELR and the area of the second emissive layer ELG when viewed from above the plane (e.g., in a plan view). However, the present disclosure is not limited thereto, and the area of the first emissive layer ELR, the area of the second emissive layer ELG, and the area of the third emissive layer ELB may be variously modified as needed or desired.

The first contact hole CNR, the second contact hole CNG, and the third contact hole CNB may not overlap with the first data line DLR, the second data line DLG, and the third data line DLB when viewed from above the plane (e.g., in a plan view).

The third anode AEB may include a first portion AEB1, a second portion AEB2, and a third portion AEB3.

The first portion AEB1, the second portion AEB2, and the third portion AEB3 may be disposed under the third emissive layer ELB. In other words, the first portion AEB1, the second portion AEB2, and the third portion AEB3 may overlap with the third emissive layer ELB when viewed from above the plane (e.g., in a plan view).

The first portion AEB1 may extend in the second direction DR2. The second portion AEB2 may extend from the first portion AEB1 in the first direction DR1. The third portion AEB3 may extend from the first portion AEB1 in the first direction DR1.

The first portion AEB1, the second portion AEB2, and the third portion AEB3 may have a one-body shape.

The second portion AEB2 and the third portion AEB3 may be spaced apart from each other, and may face each other in the second direction DR2.

When there is no gap between the second portion AEB2 and the third portion AEB3 as in a comparative example, outgas generated in the circuit layer may not be released to the outside, and therefore, the lifetime of the third emissive layer ELB may be reduced. However, because there is a gap between the second portion AEB2 and the third portion AEB3 according to some embodiments of the present disclosure, outgas generated in the circuit layer DP_CL may be smoothly released, so that a pixel shrinkage phenomenon may be improved, and the lifetime of the third emissive layer ELB may be increased. Thus, the electronic device ED (e.g., refer to FIG. 5) having an improved reliability may be provided.

The first data line DLR, the second data line DLG, and the third data line DLB may be disposed in the circuit layer DP_CL.

The data signal VD may include a first data signal VD_R, a second data signal VD_G, and a third data signal VD_B.

The first data line DLR may extend in the second direction DR2. The first data signal VD_R may be provided to the first data line DLR.

The second data line DLG may extend in the second direction DR2. The second data line DLG may be spaced apart from the third data line DLB in the direction opposite to the first direction DR1. The second data signal VD_G may be provided to the second data line DLG. The second data signal VD_G may be different from the first data signal VD_R.

The third data line DLB may extend in the second direction DR2. The third data line DLB may be spaced apart from the second data line DLG in the first direction DR1. The third data line DLB may be disposed between the first data line DLR and the second data line DLG. The third data signal VD_B may be provided to the third data line DLB. The third data signal VD_B may be different from the first data signal VD_R and the second data signal VD_G.

The first data line DLR, the second data line DLG, and the third data line DLB may overlap with the third anode AEB when viewed from above the plane (e.g., in a plan view).

The first data line DLR, the second data line DLG, and the third data line DLB may not overlap with the first anode AER and the second anode AEG when viewed from above the plane (e.g., in a plan view).

The second data line DLG and the third data line DLB, when viewed from above the plane (e.g., in a plan view), may overlap with the first portion AEB1, and may not overlap with the second portion AEB2 and the third portion AEB3.

The first data line DLR, when viewed from above the plane (e.g., in a plan view), may overlap with the second portion AEB2 and the third portion AEB3, and may not overlap with the first portion AEB1.

The third emissive layer ELB may be disposed on the third anode AEB. The third emissive layer ELB may include a first emissive portion ELB1, a second emissive portion ELB2, and a third emissive portion ELB3. The first to third emissive portions ELB1 to ELB3 may be disposed on the first to third portions AEB1 to AEB3, respectively.

The first emissive portion ELB1 may correspond to the shape of the first portion AEB1. The first emissive portion ELB1 may overlap with the first portion AEB1 when viewed from above the plane (e.g., in a plan view).

The second emissive portion ELB2 may correspond to the shape of the second portion AEB2. The second emissive portion ELB2 may overlap with the second portion AEB2 when viewed from above the plane (e.g., in a plan view).

The third emissive portion ELB3 may correspond to the shape of the third portion AEB3. The third emissive portion ELB3 may overlap with the third portion AEB3 when viewed from above the plane (e.g., in a plan view).

The first emissive portion ELB1, the second emissive portion ELB2, and the third emissive portion ELB3 may have a one-body shape.

TABLE 1

| | | |
|---|---|---|
| Color | Luminance | Current |

| | | | |
|---|---|---|---|
| W | 500 | nit | — |
| R | 121 | nit | 47 nA |
| G | 349 | nit | 44 nA |
| B | 30 | nit | 82 nA |

Table 1 shows the luminance and current of a red light, a green light, and a blue light desired for the display panel DP to display a white light of 500 nits. In other words, in order for the display panel DP to display a white light of 500 nits, a current of 47 nano Ampere (nA) may be provided to the first sub-pixel PXR so that the first sub-pixel PXR may emit light at 121 nits, a current of 44 nA may be provided to the second sub-pixel PXG so that the second sub-pixel PXG may emit light at 349 nits, and a current of 82 nA may be provided to the third sub-pixel PXB so that the third sub-pixel PXB may emit light at 30 nits.

The luminance of the third sub-pixel PXB desired for the display panel DP to display a white light having a desired luminance (e.g., a certain or predetermined luminance) may be lower than the luminance of the first sub-pixel PXR and the luminance of the second sub-pixel PXG.

The first emissive layer ELR and the second emissive layer ELG may include a phosphorescent material, and the third emissive layer ELB may include a fluorescent material. The third sub-pixel PXB may have lower efficiency than those of the first sub-pixel PXR and the second sub-pixel PXG, because the third emissive layer ELB includes a fluorescent material. As such, the current provided to the third sub-pixel PXB desired for the display panel DP to display a white light having a desired luminance (e.g., a certain or predetermined luminance) may be higher than the current provided to each of the first sub-pixel PXR and the second sub-pixel PXG.

Copy Mura defects of horizontal/vertical line stains of the panel may be measured through a specific test pattern that displays black or white. The Copy Mura defects may occur when a swing of the data signals VD_R, VD_G, and VD_B has a coupling influence on the anode AE.

According to some embodiments of the present disclosure, a relatively higher current may be provided to the third anode AEB when the specific test pattern displaying white is measured. The first data line DLR, the second data line DLG, and the third data line DLB may overlap with the third anode AEB when viewed from above the plane (e.g., in a plan view). A coupling influence between the first data line DLR, the second data line DLG, and the third data line DLB and the third anode AEB may be reduced. A visibility of Copy Mura defects may be lowered. Thus, the electronic device ED having an improved display quality may be provided.

In addition, according to some embodiments of the present disclosure, the plurality of data lines DLR, DLG, and DLB may all be disposed under the light emitting element OLED of the third sub-pixel PXB that emits a blue light. As compared with when the first data line DLR, the second data line DLG, and the third data line DLB are disposed under the light emitting element OLED of the first sub-pixel PXR, the light emitting element OLED of the second sub-pixel PXG, and the light emitting element OLED of the third sub-pixel PXB, respectively, the Copy Mura defect level may be improved by about 50% or more. Thus, the electronic device ED having an improved display quality may be provided.

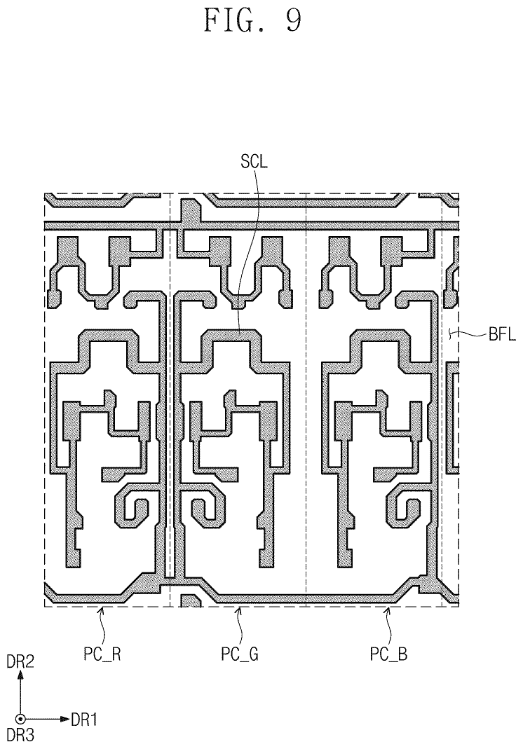

FIG. 9 is a plan view illustrating a portion of the circuit layer according to an embodiment of the present disclosure.

Referring to FIGS. 6 to 9, a pixel circuit PC may include a first pixel circuit PC_R, a second pixel circuit PC_G, and a third pixel circuit PC_B. The first pixel circuit PC_R, the second pixel circuit PC_G, and the third pixel circuit PC_B may be arranged along the first direction DR1. The first pixel circuit PC_R, the second pixel circuit PC_G, and the third pixel circuit PC_B may be repeated as a set along the first direction DR1 and the second direction DR2. For example, the first pixel circuit PC_R may be disposed in a portion adjacent to the third pixel circuit PC_B in the first direction DR1.

The first pixel circuit PC_R may refer to the pixel circuit PC of the first sub-pixel PXR. The second pixel circuit PC_G may refer to the pixel circuit PC of the second sub-pixel PXG. The third pixel circuit PC_B may refer to the pixel circuit PC of the third sub-pixel PXB.

The first pixel circuit PC_R and the third pixel circuit PC_B may have the same or substantially the same shape as each other, and the second pixel circuit PC_G may have a shape symmetrical to or substantially symmetrical to those of the first pixel circuit PC_R and the third pixel circuit PC_B with respect to an axis extending in the second direction DR2.

Each of the first pixel circuit PC_R, the second pixel circuit PC_G, and the third pixel circuit PC_B may include a semiconductor pattern SCL.

The semiconductor pattern SCL may be disposed on the buffer layer BFL. The semiconductor pattern SCL may include a first material. The first material may include a silicon semiconductor. For example, the semiconductor pattern SCL may include a low temperature polycrystalline silicon (LTPS).

The semiconductor pattern SCL may include the semiconductor pattern of each of the transistors T1 to T10 (e.g., refer to FIG. 7) included in the pixel circuit PC. For example, the semiconductor pattern SCL may include the semiconductor pattern SC, AL, DR, and SL of the transistor TR.

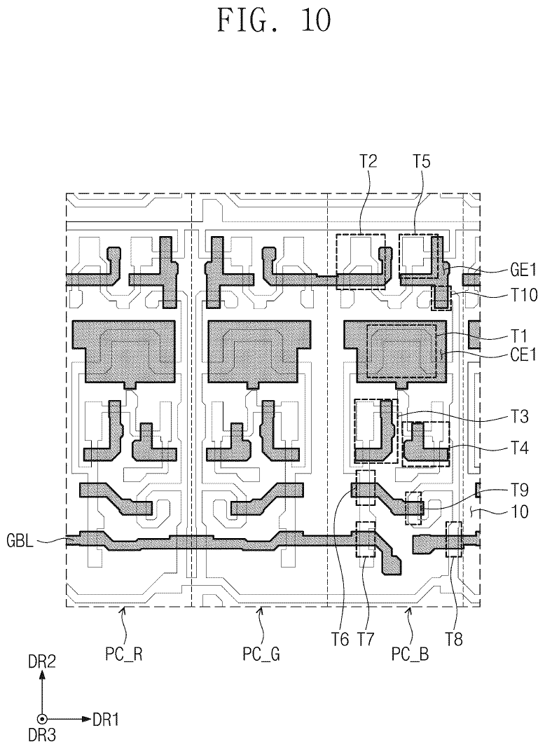

FIG. 10 is a plan view illustrating a portion of the circuit layer according to an embodiment of the present disclosure.

Referring to FIGS. 6 to 10, the semiconductor pattern SCL may be covered by the first insulating layer 10.

A first gate pattern layer may be formed on the first insulating layer 10. The first gate pattern layer may include a metal, an alloy, a conductive metal oxide, or a transparent conductive material. For example, the first gate pattern layer may include silver (Ag), an alloy containing silver, molybdenum (Mo), an alloy containing molybdenum, aluminum (AI), an alloy containing aluminum, aluminum nitride (AlN), tungsten (W), tungsten nitride (WN), copper (Cu), indium tin oxide (ITO), or indium zinc oxide (IZO), but the present disclosure is not particularly limited thereto.

The first gate pattern layer may include a first gate electrode GE1, a first electrode CE1, and a bias scan line GBL.

The bias scan line GBL may extend in the first direction DR1. The bias scan line GBL may correspond to the i-th bias scan line GBLi illustrated in FIG. 7. The bias scan line GBL may overlap with at least a portion of the semiconductor pattern SCL when viewed from above the plane (e.g., in a plan view). The bias scan line GBL may constitute the seventh transistor T7 and the eighth transistor T8 together with the semiconductor pattern SCL.

The first electrode CE1 may be formed in an island shape. The first electrode CE1 may overlap with at least a portion of the semiconductor pattern SCL when viewed from above the plane (e.g., in a plan view). The first electrode CE1 may constitute the first transistor T1 together with the semiconductor pattern SCL. The first electrode CE1 may be referred to as the first gate G1.

The first gate electrode GE1 may be formed in an island shape. The first gate electrode GE1 may be provided in a plurality. The plurality of gate electrodes GE1 may overlap with at least a portion of the semiconductor pattern SCL. The plurality of gate electrodes GE1 may constitute the second to sixth transistors T2 to T6, the ninth transistor T9, and the tenth transistor T10 together with the semiconductor pattern SCL.

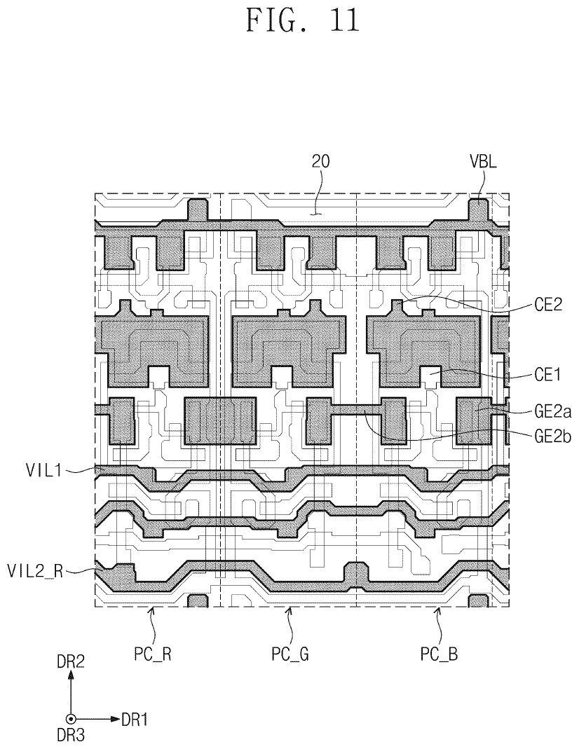

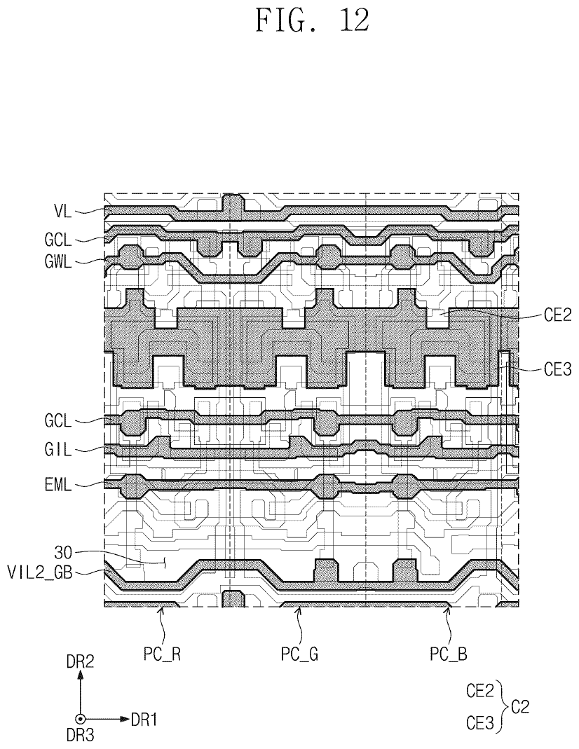

FIG. 11 is a plan view illustrating a portion of the circuit layer according to an embodiment of the present disclosure.

Referring to FIGS. 6 to 11, the second insulating layer 20 may cover the first gate pattern layer. The second insulating layer 20 may be disposed on the first insulating layer 10. A second gate pattern layer may be formed on the second insulating layer 20. The second gate pattern layer may include a metal, an alloy, a conductive metal oxide, or a transparent conductive material.

The second gate pattern layer may include second gate electrodes GE2a and GE2b, the bias line VBL, a second electrode CE2, the first initialization line VIL1, and a second-first initialization line VIL2_R.

Each of the second gate electrodes GE2a and GE2b may be provided in an island shape. The second gate electrodes GE2a and GE2b may include the second-first gate electrode GE2a and the second-second gate electrode GE2b.

The second-first gate electrode GE2a may be constituted by the upper gate of the fourth transistor T4.

The second-second gate electrode GE2b may be constituted by the upper gate of the third transistor T3.

The bias line VBL may extend in the first direction DR1. The bias voltage VBIAS may be provided to the bias line VBL. The bias line VBL may be constituted by the upper gates of the second transistor T2 and the fifth transistor T5.

The second electrode CE2 may overlap with the first electrode CE1. The first electrode CE1 and the second electrode CE2 may constitute the first capacitor C1. The second electrode CE2 may be referred to as the second gate G2.

The first initialization line VIL1 may extend in the first direction DR1. The first initialization voltage VINT may be provided to the first initialization line VIL1.

The second-first initialization line VIL2_R may extend in the first direction DR1. The second-first initialization line VIL2_R may be included in the second initialization line VIL2. The second-first initialization line VIL2_R may be electrically connected with the first pixel circuit PC_R that emits a red light. The second initialization voltage VAINT may be provided to the second-first initialization line VIL2_R.

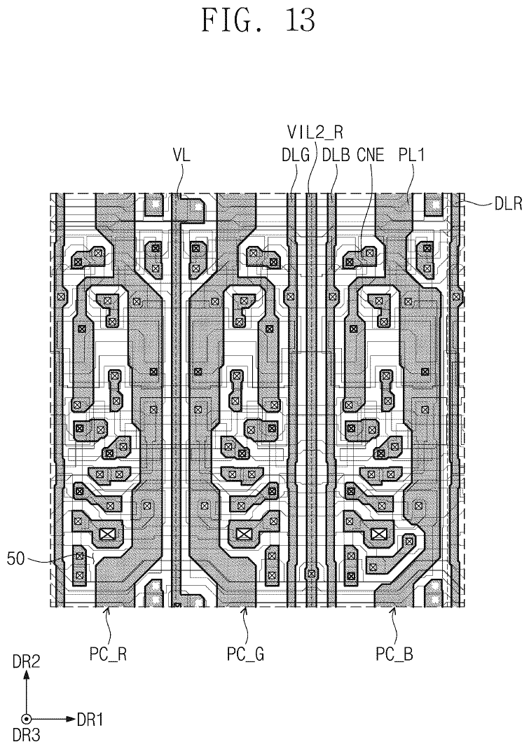

FIG. 12 is a plan view illustrating a portion of the circuit layer according to an embodiment of the present disclosure.

Referring to FIGS. 6 to 12, the third insulating layer 30 may cover the second gate pattern layer. The third insulating layer 30 may cover the second insulating layer 20. A third gate pattern layer may be formed on the third insulating layer 30. The third gate pattern layer may include a metal, an alloy, a conductive metal oxide, or a transparent conductive material.

The third gate pattern layer may include the reference line VL, a compensation scan line GCL, a write scan line GWL, a third electrode CE3, an initialization scan line GIL, an emission line EML, and a second-second initialization line VIL2_GB.

The reference line VL may extend in the first direction DR1. The reference voltage VR may be provided to the reference line VL.

The compensation scan line GCL may extend in the first direction DR1. The compensation scan line GCL may correspond to the i-th compensation scan line GCLi illustrated in FIG. 7. The compensation scan signal GCi may be provided to the compensation scan line GCL.

The compensation scan line GCL may be provided in a plurality. The plurality of compensation scan lines GCL may be spaced apart from each other in the second direction DR2.

The write scan line GWL may extend in the first direction DR1. The write scan line GWL may correspond to the i-th write scan line GWLi illustrated in FIG. 7. The write scan signal GWi may be provided to the write scan line GWL.

The third electrode CE3 may overlap with the second electrode CE2. The second electrode CE2 and the third electrode CE3 may constitute the second capacitor C2. The third electrode CE3 may be referred to as the third gate G3.

The initialization scan line GIL may extend in the first direction DR1. The initialization scan line GIL may correspond to the i-th initialization scan line GILi illustrated in FIG. 7. The initialization scan signal Gli may be provided to the initialization scan line GIL.

The emission line EML may extend in the first direction DR1. The emission line EML may correspond to the i-th emission line EMLi illustrated in FIG. 7. The emission signal EMi may be provided to the emission line EML.

The second-second initialization line VIL2_GB may extend in the first direction DR1. The second-second initialization line VIL2_GB may be included in the second initialization line VIL2. The second-second initialization line VIL2_GB may be electrically connected with the second pixel circuit PC_G that emits a green light, and the third pixel circuit PC_B that emits a blue light. The second initialization voltage VAINT may be provided to the second-second initialization line VIL2_GB.

For example, a first voltage level of the second initialization voltage VAINT provided to the second-second initialization line VIL_GB may be different from a second voltage level of the second initialization voltage VAINT provided to the second-first initialization line VIL_R. However, the present disclosure is not limited thereto, and the first voltage level and the second voltage level may be variously modified as needed or desired. For example, the first voltage level and the second voltage level may be equal to or substantially equal to each other.

FIG. 13 is a plan view illustrating a portion of the circuit layer according to an embodiment of the present disclosure.

Referring to FIGS. 6 to 13, the fifth insulating layer 50 may be disposed over the third insulating layer 30. A data pattern layer may be disposed on the fifth insulating layer 50. The data pattern layer may include, for example, a metal, an alloy, a conductive metal oxide, or a transparent conductive material.

The data pattern layer may include the first data line DLR, the second data line DLG, the third data line DLB, the first power line PL1, and a plurality of connecting electrodes CNE. Each of the plurality of connecting electrodes CNE may electrically connect two components to each other through a contact hole.

Each of the first data line DLR, the second data line DLG, and the third data line DLB may extend in the second direction DR2. The first data line DLR, the second data line DLG, and the third data line DLB may be spaced apart from one another in the first direction DR1. The first data line DLR, the second data line DLG, and the third data line DLB may correspond to the j-th data line DLj illustrated in FIG. 7.

The first data line DLR may be disposed in the area where the first pixel circuit PC_R is disposed. The first data line DLR may be connected with the second transistor T2 of the first pixel circuit PC_R through a connecting electrode CNE. The first data signal VD_R may be provided to the first data line DLR. The first data signal VD_R may correspond to the data signal VD.

The second data line DLG may be disposed in the area where the second pixel circuit PC_G is disposed. The second data line DLG may be connected with the second transistor T2 of the second pixel circuit PC_G through a connecting electrode CNE. The second data signal VD_G may be provided to the second data line DLG. The second data signal VD_G may correspond to the data signal VD.

The third data line DLB may be disposed in the area where the third pixel circuit PC_B is disposed. The third data line DLB may be connected with the second transistor T2 of the third pixel circuit PC_B through a connecting electrode CNE. The third data signal VD_B may be provided to the third data line DLB. The third data signal VD_B may correspond to the data signal VD.

The first data line DLR, the second data line DLG, and the third data line DLB may be formed in the same layer as that of the plurality of connecting electrodes CNE. The plurality of connecting electrodes CNE may correspond to the second connecting electrode CNE2.

The first power line PL1 may extend in the second direction DR2. The first voltage ELVDD may be provided to the first power line PL1. The first power line PL1 may be connected with the first pixel circuit PC_R, the second pixel circuit PC_G, and the third pixel circuit PC_B through a contact.

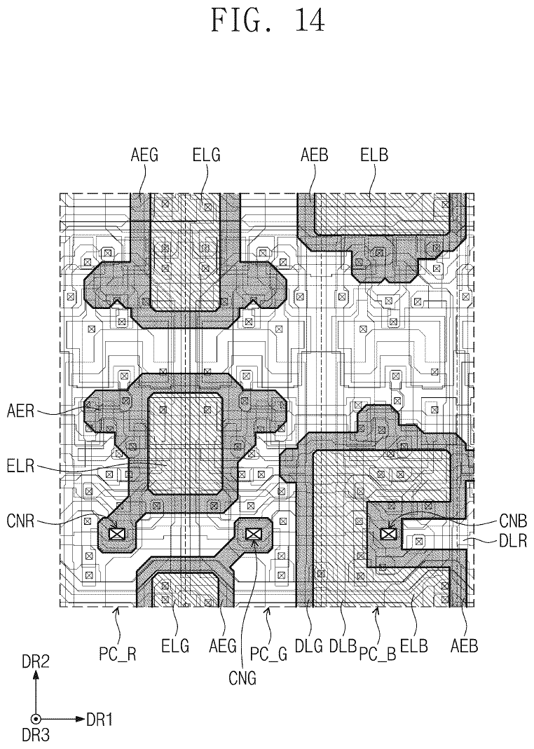

FIG. 14 is a plan view illustrating a portion of the light emitting element layer according to an embodiment of the present disclosure.

Referring to FIGS. 5 to 14, the sixth insulating layer 60 may cover the data pattern layer. The sixth insulating layer 60 may cover the fifth insulating layer 50. The light emitting element layer DP_ED may be disposed on the sixth insulating layer 60.

The first anode AER, the second anode AEG, and the third anode AEB may be disposed on the sixth insulating layer 60.

The first anode AER, the second anode AEG, and the third anode AEB may correspond to the anode AE illustrated in FIG. 7.

The first pixel circuit PC_R may be connected with the first anode AER through the first contact hole CNR.

The second pixel circuit PC_G may be connected with the second anode AEG through the second contact hole CNG.

The third pixel circuit PC_B may be connected with the third anode AEB through the third contact hole CNB.

The first emissive layer ELR may be disposed on the first anode AER. The second emissive layer ELG may be disposed on the second anode AEG. The third emissive layer ELB may be disposed on the third anode AEB. The first emissive layer ELR, the second emissive layer ELG, and the third emissive layer ELB may correspond to the emissive layer EL illustrated in FIG. 7.

The first emissive layer ELR may overlap with the first anode AER. The second emissive layer ELG may overlap with the second anode AEG. The third emissive layer ELB may overlap with the third anode AEB.

The first data line DLR, the second data line DLG, and the third data line DLB may overlap with the third anode AEB when viewed from above the plane (e.g., in a plan view).

According to some embodiments of the present disclosure, the plurality of data lines DLR, DLG, and DLB may all be disposed under the light emitting element OLED of the third sub-pixel PXB that emits a blue light. As compared with a comparative example in which the first data line DLR, the second data line DLG, and the third data line DLB are disposed under the light emitting element OLED of the first sub-pixel PXR, the light emitting element OLED of the second sub-pixel PXG, and the light emitting element OLED of the third sub-pixel PXB, respectively, the Copy Mura defect level may be improved by about 50% or more. A coupling influence between the first data line DLR, the second data line DLG, and the third data line DLB and the third anode AEB may be reduced. The visibility of Copy Mura defects may be lowered. Thus, the electronic device ED having an improved display quality may be provided.

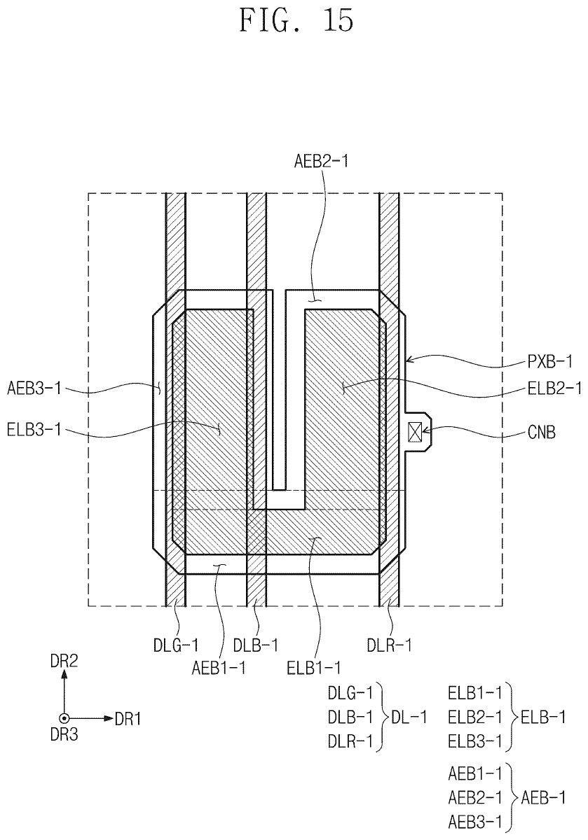

FIG. 15 is a plan view illustrating a portion of the display panel according to an embodiment of the present disclosure. In FIG. 15, the same or substantially the same components as those described above with reference to FIG. 8 are assigned with the same reference numerals, and thus, redundant description thereof may not be repeated.

Referring to FIGS. 6 and 15, a light emitting element OLED of a third sub-pixel PXB-1 may include a third anode AEB-1 and a third emissive layer ELB-1. The third anode AEB-1 and the third emissive layer ELB-1 may be disposed in the light emitting element layer DP_ED.

The third anode AEB-1 may be electrically connected to the pixel circuit PC of the third sub-pixel PXB through the third contact hole CNB. The third emissive layer ELB-1 may be disposed on the third anode AEB-1. The third emissive layer ELB-1 may emit a blue light.

The third anode AEB-1 may cover the third emissive layer ELB-1 when viewed from above the plane (e.g., in a plan view). In other words, the area of the third anode AEB-1 may be greater than the area of the third emissive layer ELB-1 when viewed from above the plane (e.g., in a plan view).

The third anode AEB-1 may include a first portion AEB1-1, a second portion AEB2-1, and a third portion AEB3-1.

The first portion AEB1-1, the second portion AEB2-1, and the third portion AEB3-1 may be disposed under the third emissive layer ELB-1. In other words, the first portion AEB1-1, the second portion AEB2-1, and the third portion AEB3-1 may overlap with the third emissive layer ELB-1 when viewed from above the plane (e.g., in a plan view).

The first portion AEB1-1 may extend in the first direction DR1. The second portion AEB2-1 may extend from the first portion AEB1-1 in the second direction DR2. The third portion AEB3-1 may extend from the first portion AEB1-1 in the second direction DR2.

The first portion AEB1-1, the second portion AEB2-1, and the third portion AEB3-1 may have a one-body shape.

The second portion AEB2-1 and the third portion AEB3-1 may be spaced apart from each other, and may face each other in the first direction DR1.

When there is no gap between the second portion and the third portion as in a comparative example, outgas generated in the circuit layer may not be released to the outside, and therefore, the lifetime of the third emissive layer may be reduced. However, because there is a gap between the second portion AEB2-1 and the third portion AEB3-1 according to some embodiments of the present disclosure, outgas generated in the circuit layer DP_CL may be smoothly released, so that a pixel shrinkage phenomenon may be improved, and the lifetime of the third emissive layer ELB-1 may be increased. Thus, the electronic device ED (e.g., refer to FIG. 5) having an improved reliability may be provided.

A first data line DLR-1, a second data line DLG-1, and a third data line DLB-1 may be disposed in the circuit layer DP_CL.

The first data line DLR-1, the second data line DLG-1, and the third data line DLB-1 may overlap with the third anode AEB-1 when viewed from above the plane (e.g., in a plan view).

The third emissive layer ELB-1 may be disposed on the third anode AEB-1. The third emissive layer ELB-1 may include a first emissive portion ELB1-1, a second emissive portion ELB2-1, and a third emissive portion ELB3-1. The first to third emissive portions ELB1 to ELB3 may be disposed on the first to third portions AEB1 to AEB3, respectively.

The first emissive portion ELB1-1 may correspond to the shape of the first portion AEB1-1. The first emissive portion ELB1-1 may overlap with the first portion AEB1-1 when viewed from above the plane (e.g., in a plan view).

The second emissive portion ELB2-1 may correspond to the shape of the second portion AEB2-1. The second emissive portion ELB2-1 may overlap with the second portion AEB2-1 when viewed from above the plane (e.g., in a plan view).

The third emissive portion ELB3-1 may correspond to the shape of the third portion AEB3-1. The third emissive portion ELB3-1 may overlap with the third portion AEB3-1 when viewed from above the plane (e.g., in a plan view).

The first emissive portion ELB1-1, the second emissive portion ELB2-1, and the third emissive portion ELB3-1 may have a one-body shape.

According to some embodiments of the present disclosure, the plurality of data lines DLR-1, DLG-1, and DLB-1 may all be disposed under the light emitting element OLED of the third sub-pixel PXB-1 that emits a blue light. A relatively higher current may be provided to the third anode AEB-1 when a specific test pattern displaying white is measured. The first data line DLR-1, the second data line DLG-1, and the third data line DLB-1 may overlap with the third anode AEB-1 when viewed from above the plane (e.g., in a plan view). A coupling influence between the first data line DLR-1, the second data line DLG-1, and the third data line DLB-1 and the third anode AEB-1 may be reduced. The visibility of Copy Mura defects may be lowered. Thus, the electronic device ED (e.g., refer to FIG. 5) having an improved display quality may be provided.

As described above, a relatively higher current may be provided to the first anode of the sub-pixel for emitting a blue light when the specific test pattern displaying white is measured. The first data line, the second data line, and the third data line may overlap with the third anode when viewed from above the plane (e.g., in a plan view). The coupling influence between the first data line, the second data line, and the third data line and the third anode may be reduced. The visibility of Copy Mura defects may be lowered. Thus, the electronic device having an improved display quality may be provided.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a display panel comprising a circuit layer, and a light emitting element layer on the circuit layer,
wherein the circuit layer comprises:
a base layer;
a transistor on the base layer;
a connecting electrode electrically connected with the transistor; and
a plurality of data lines above the transistor,
wherein the light emitting element layer comprises:
a first anode on the circuit layer, and electrically connected with the connecting electrode;
a first emissive layer on the first anode; and
a cathode on the first emissive layer,
wherein the plurality of data lines comprises:
a first data line extending in a first direction;
a second data line spaced from the first data line in a second direction crossing the first direction; and
a third data line spaced from the second data line in the second direction, and
wherein each of the plurality of data lines overlaps with the first anode in a plan view.

2. The electronic device of claim 1, wherein the first data line is configured to receive a first data signal, the second data line is configured to receive a second data signal different from the first data signal, and the third data line is configured to receive a third data signal different from the first data signal and the second data signal.

3. The electronic device of claim 1, wherein the first emissive layer is configured to emit a blue light.

4. The electronic device of claim 1, wherein the light emitting element layer further comprises:
a second anode on the circuit layer;
a second emissive layer on the second anode;
a third anode on the circuit layer; and
a third emissive layer on the third anode.

5. The electronic device of claim 4, wherein the plurality of data lines do not overlap with the second anode and the third anode in a plan view.

6. The electronic device of claim 1, wherein the first anode comprises a first portion extending in the first direction, a second portion extending from the first portion in the second direction, and a third portion extending from the first portion in the second direction.

7. The electronic device of claim 6, wherein, in a plan view, the first data line and the second data line overlap with the first portion, and the third data line overlaps with the second portion and the third portion.

8. The electronic device of claim 6, wherein the first emissive layer comprises a first emissive portion corresponding to a shape of the first portion, a second emissive portion corresponding to a shape of the second portion, and a third emissive portion corresponding to a shape of the third portion.

9. The electronic device of claim 6, wherein the second portion and the third portion are spaced from each other and face each other in the first direction.

10. The electronic device of claim 6, wherein the first portion, the second portion, and the third portion have a one-body shape.

11. The electronic device of claim 1, wherein the first anode comprises a first portion extending in the second direction, a second portion extending from the first portion in the first direction, and a third portion extending from the first portion in the first direction.

12. The electronic device of claim 11, wherein the second portion and the third portion are spaced from each other and face each other in the second direction.

13. The electronic device of claim 1, wherein the plurality of data lines is located at a same layer as that of the connecting electrode.

14. An electronic device comprising:
a display panel comprising a circuit layer comprising a plurality of data lines, and a light emitting element layer on the circuit layer,
wherein the light emitting element layer comprises:
a first anode on the circuit layer;
a first emissive layer on the first anode, and configured to provide a blue light;
a second anode on the circuit layer;
a second emissive layer on the second anode, and configured to provide a green light; and
a cathode on the first emissive layer and the second emissive layer,
wherein the plurality of data lines comprises:
a first data line extending in a first direction; and
a second data line spaced from the first data line in a second direction crossing the first direction, and
wherein the first data line and the second data line overlap with the first anode, and do not overlap with the second anode in a plan view.

15. The electronic device of claim 14, wherein the first anode comprises a first portion extending in the first direction, a second portion extending from the first portion in the second direction, and a third portion extending from the first portion in the second direction.

16. The electronic device of claim 15, wherein the first data line and the second data line overlap with the first portion in a plan view.

17. The electronic device of claim 15, wherein the first emissive layer comprises a first emissive portion corresponding to a shape of the first portion, a second emissive portion corresponding to a shape of the second portion, and a third emissive portion corresponding to a shape of the third portion.

18. The electronic device of claim 14, wherein the first anode comprises a first portion extending in the second direction, a second portion extending from the first portion in the first direction, and a third portion extending from the first portion in the first direction.

19. The electronic device of claim 18, wherein the first portion and the third portion are spaced from each other and face each other in the second direction.

20. The electronic device of claim 14, wherein the first data line is configured to receive a first data signal, and the second data line is configured to receive a second data signal different from the first data signal.
